(19) United States
(12) Patent Application Publication
(10) Pub. No.: US 2025/0357236 A1
(43) Pub. Date: Nov. 20, 2025

(54) BILAYER ENCAPSULATION STRUCTURE FOR LIQUID METAL INTERCONNECTS

(71) Applicant: Intel Corporation, Santa Clara, CA (US)

(72) Inventors: Sangeon Lee, Chandler, AZ (US); Tingting Gao, Chandler, AZ (US); Xiao Lu, Chandler, AZ (US)

(73) Assignee: Intel Corporation, Santa Clara, CA (US)

(21) Appl. No.: 18/666,640

(22) Filed: May 16, 2024

(51) Int. Cl. H01L 23/31; H01L 21/56; H01L 23/29; H01L 23/528; H01L 23/532

(52) U.S. Cl. CPC H01L 23/3192; H01L 21/56; H01L 23/291; H01L 23/293; H01L 23/5283; H01L 23/53209

(57) ABSTRACT

Apparatuses, containment structures, and techniques related to encapsulating liquid metal interconnects are discussed. A liquid metal interconnect is within a cavity defined by an electronics substrate and an opening in a confinement layer over the electronics substrate. A bilayer containment structure is on the confinement layer and over the cavity to encapsulate the liquid metal interconnect within the cavity. The bilayer includes a porous material layer over the cavity and a self-healing material on the porous material layer.

### BACKGROUND

The increasing demand for enhanced computing power, coupled with growing requirements for expanded memory and high-speed signaling input-output (HSIO) bandwidth, is driving the exponential growth of board/second level interconnect (SLI) pin count, processor package size, and thermo-mechanical enabling complexity. There is a rising interest in cost-effective separable interconnect solutions featuring a late attach option, which improve inventory control and allow for the replacement of processor packages. This enables in-field upgrades and repairs, which fulfil reliability, availability, and serviceability requirements. Traditional interconnect technologies including socketable land grid array (LGA) or permanently soldered ball grid array (BGA) have inherent limitations that are not scalable and do not meet the evolving demands of future yield, performance, total cost of ownership, and system on chip (SoC) density requirements.

Recent advancements in material development have spotlighted liquid metal alloys such as gallium-based liquid metal alloys, which are renowned for their non-toxicity at room temperature and exceptional electrical and thermal conductivity. These materials have great potential as electrode materials for cutting-edge electronics with innovative designs. Unlike traditional metals in a solid state, the intrinsic softness of liquid metals allows for easy dispensing, patterning, deformation, and stretching to achieve desired structures. Liquid metals possess unique properties combining metallic and fluidic characteristics, including high electrical and thermal conductivity, low toxicity, benign biocompatibility, a viscosity similar to water, and others.

Liquid metal array socket technology offers high conductivity and low resistance interconnect, facilitating pin count scaling without the need for increased load compared to LGA, simplifying loading complexities. Significant research and development efforts have been dedicated to implementing liquid metal interconnect technology in SLI board/socket configurations and first level interconnect (FLI) die/substrate applications. These distinctive attributes make liquid metals widely applicable in flexible electronics, immersion cooling solutions, and socket technology.

However, deployment of liquid metals faces difficulties. For example, a significant technical hurdle involves moisture reaching the liquid metals, which exacerbates the temperature-humidity reliability issues of liquid metals. This reliability problem is commonly referred to as the snaking issue and is caused by, for example, gallium oxide monohydroxide crystallites (GaOOH) that form on gallium-based liquid metals in the presence of moisture and leads to the production of hydrogen through the reaction between gallium oxide and moisture, resulting in an expansion effect.

It is with respect to these and other considerations that the present improvements have been needed. Such improvements may become critical as the desire to deploy liquid metal interconnects becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional side view of an example system having a liquid metal interconnect encapsulated within a cavity covered by a bilayer containment structure having a porous material layer and a self-healing material layer;

FIG. 2 illustrates a cross-sectional side view of the example system of FIG. 1 and mechanisms for preventing moisture and venting hydrogen;

FIG. 3 illustrates exemplary characteristics of a porous material layer including a top-down view, a cross-sectional side view, and thickness characteristics;

FIG. 4 provides a cross-sectional top-down view of the system of FIG. 1 to illustrate an example layout of conductive pins penetrating a bilayer containment structure;

FIG. 5 illustrates a cross-sectional side view of the system of FIG. 1 after removal of conductive pin 109 and self-healing of the bilayer containment structure;

FIG. 6 provides a cross-sectional top-down view of the system of FIG. 1 to illustrate an exemplary self-healing bilayer containment structure;

FIG. 7 is a flow diagram illustrating an example process for fabricating and assembling integrated circuit devices having a liquid metal interconnect encapsulated within a cavity covered by a bilayer containment structure having a porous material layer and a self-healing material layer;

FIGS. 8, 9, 10, 11, 12, 13, 14, 15, and 16 illustrate example integrated circuit device structures as the operations of process are performed;

FIG. 17 illustrates exemplary systems employing an assembly including a liquid metal interconnect encapsulated within a cavity covered by a bilayer containment structure having a porous material layer and a self-healing material layer; and

FIG. 18 is a functional block diagram of a computing device, all arranged in accordance with at least some implementations of the present disclosure.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized, and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that some embodiments may be practiced without these specific details. In some instances, well-known methods and devices are shown in block diagram form, rather than in detail, to avoid obscuring other aspects of an embodiment. Reference throughout this specification to “an embodiment” or “one embodiment” means that a particular feature, structure, function, or characteristic described in connection with the embodiment is included in at least one embodiment. Thus, the appearances of the phrase “in an embodiment” or “in one embodiment” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

References in the specification to “one implementation”, “an implementation”, “an example implementation”, etc., indicate that the implementation described may include a particular feature, structure, or characteristic, but every embodiment may not necessarily include the particular feature, structure, or characteristic. Moreover, such phrases are not necessarily referring to the same implementation. Further, when a particular feature, structure, or characteristic is described in connection with an embodiment, it is submitted that it is within the knowledge of one skilled in the art to effect such feature, structure, or characteristic in connection with other implementations whether or not explicitly described herein.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

Apparatuses, integrated circuit devices, techniques, and systems are described herein related to the design and fabrication of a bilayer encapsulation structure to enclose a liquid metal interconnect within a cavity for improved protection against moisture and ventilation of hydrogen gas.

As discussed, liquid metals, including gallium-based liquid metal alloys are of interest for deployment as interconnects due to easy dispensing, patterning, deformation and stretching to achieve desired structures, high electrical and thermal conductivity, low toxicity, benign biocompatibility, a viscosity similar to water, and others. However, deployment of liquid metals faces difficulties due, in part, to temperature-humidity reliability issues caused by the presence of moisture and production of hydrogen when the liquid metal is encapsulated within a cavity. For example, liquid metal interconnects may be deposited within cavities or openings of a containment structure and on solid state metal pads or interconnects of an electronics substrate. The cavities may then be covered by a layer and a pin from a package may puncture the layer and contact the liquid metal interconnect. Moisture may permeate the layer leading to the discussed failures such as formation of GaOOH (gallium oxide monohydroxide crystallites) on the surface of the liquid metal due to the reaction of gallium and water, which produces hydrogen bubbles and the discussed snaking issues. This reaction causes the liquid metal interconnect to undesirably expand, lose its fluid characteristics, solidify, lose electrical conductivity, and others. Therefore, it is imperative to keep moisture out of the cavity while expelling hydrogen. In addition, there is a desire to remove the contact pin and re-insert the same or different contact pin in a repeated fashion such that the system can be re-used, re-configured, upgraded, etc. with a repeated use or feature.

The apparatuses, materials, and techniques discussed herein provide for a multilayer cap, such as a bilayer, that is applied on the containment structure and over the cavity that contains the liquid metal interconnect. The multilayer cap encapsulates the liquid metal interconnect within the cavity to protect it from moisture, to expel hydrogen from the cavity, and to self-heal the multilayer cap upon removal of a contact pin or other damage to the multilayer cap. The multilayer cap includes at least a bilayer of materials. The first material layer is on the containment structure and over the cavity. The first material layer is porous having a pore size in the range of about 1 nm to 500 microns. For example, the first material layer may be a polymer material having an average pore size of not less than 1 nm and not more than 500 microns. The second material layer is on the first material layer and includes a self-healing material layer. The self-healing material may include any suitable self-healing material and may include any of a metal oxide, a metalloid oxide, a gel adhesive, a microcapsule healing polymer, an epoxy resin, cross-linked polymers, thiol-based polymers, vitrimers, a copolymer with Van der Waals force, or other materials of a self-healing layer. The multilayer cap or multilayer layer encapsulates the liquid metal, protecting it from moisture, allowing venting of hydrogen gas, and removal and reapplication of contact pins through the multilayer cap or layer to advantageously eliminate the discussed snaking issue (e.g., caused by moisture contacting the liquid metal and production of hydrogen) by reducing moisture and venting hydrogen, increase reliability, and increase reusability of the liquid metal interconnect system.

The discussed multilayer cap structure includes a gas-permeable porous layer combined with a self-healing material. This gas-permeable layer or membrane effectively prevents the passage of moisture or water vapor while allowing the ejection of hydrogen. The membrane allows for the effective release of gases, preserves internal pressure, prevents moisture ingress, and reduces condensation that can often result in structural failure. As discussed, the expulsion of hydrogen is highly essential to preserve the overall shape of the liquid metal. Additionally, self-healing materials are integrated with the gas-permeable membrane, exhibiting excellent adhesion, superior anti-corrosion performance, and automatic healing efficiency. This coating automatically inhibits corrosion reactions and repairs physical damage along the punctured hole area caused by pin insertion. Therefore, an ultra-robust gas (hydrogen) permeable cap layer is formed through the incorporation of a self-healable coating material and a porous material layer multi-functional film. In some embodiments, the porous material layer is a polyurethane material. However, other polymeric materials, for example, may be deployed. The size of micropores can be controlled at a nanometer to micron unit level, allowing for the adjustment of gas permeability and preventing moisture leakage. The multilayer cap structure discussed herein allows for the use of liquid metal interconnect technology in a variety of contexts.

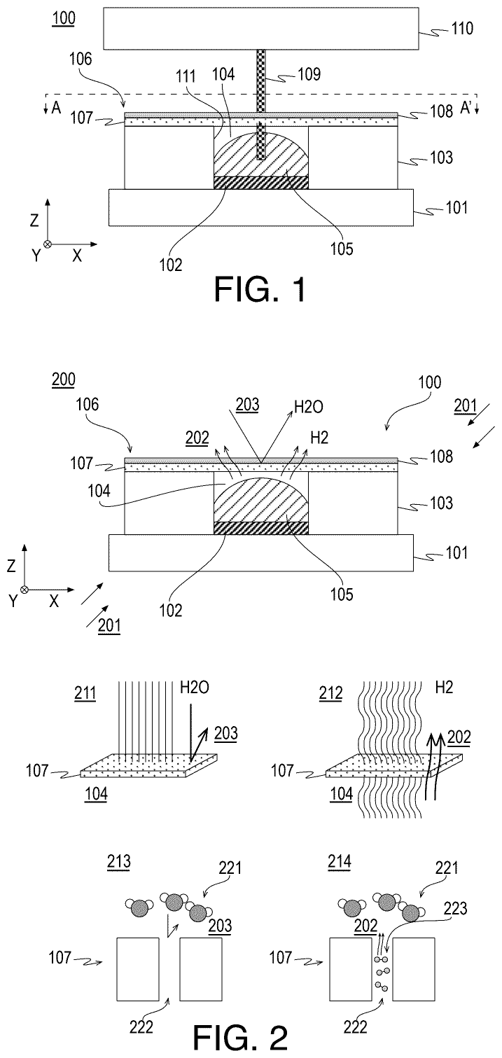

FIG. 1 illustrates a cross-sectional side view of an example system 100 having a liquid metal interconnect 105 encapsulated within a cavity 104 covered by a bilayer containment structure 106 having a porous material layer 107 and a self-healing material layer 108, arranged in accordance with at least some implementations of the present disclosure. As shown in FIG. 1, system 100 includes a microelectronics board 101 including a number of interconnect structures 102. For example, interconnect structures 102 may be metal bond pads. Confinement layer 103 is on or over microelectronics board 101 and confinement layer 103 includes openings that, in part, define a sidewall 111 of cavity 104. As shown, interconnect structures 102 of microelectronics board 101 are within openings of confinement layer 103. Liquid metal interconnect 105 is on interconnect structure 102 and within cavity 104. Bilayer containment structure 106 is on confinement layer 103 and over cavity 104 such that confinement layer 103, bilayer containment structure 106, and microelectronics board 101 (i.e., interconnect structure 102 of microelectronics board 101 and, optionally, other surface elements of microelectronics board 101) fully encapsulate liquid metal interconnect 105 within a portion of the volume of cavity 104. Bilayer containment structure 106 may be characterized as a multilayer structure, a multilayer stack, or the like.

Also as shown, a conductive pin 109 of a package substrate 110 extends through bilayer containment structure 106 to contact liquid metal interconnect 105. For example, electrical connection is made between microelectronics board 101 and package substrate 110 through interconnect structure 102, liquid metal interconnect 105, and conductive pin 109. In some embodiments, conductive pins 109 may be characterized as socket pins or socket interconnects. As discussed, it is desirable to seal liquid metal interconnect 105 from moisture, to vent hydrogen from the portion of cavity 104 surrounding liquid metal interconnect 105, and to heal bilayer containment structure 106 after removal of conductive pin 109 and/or due to other damage to bilayer containment structure 106. This functionality is achieved by porous material layer 107 and a self-healing material layer 108 of bilayer containment structure 106 as discussed further herein below.

As shown, system 100 provides a socketing architecture with liquid metal materials. In the illustrated context, cavity 104 is on microelectronics board 101 and liquid metal interconnects 105 provide for a second level interconnect (SLI). However, first level interconnect (FLI) architectures may also use liquid metal systems. For example, microelectronics board 101 may be any suitable electronics substrate such as a board, an interposer, a package substrate, or others. As used herein, liquid metal materials are material compositions that comprise a metal, and the material composition exhibits a liquid phase at or near room temperature. In some embodiments, the liquid metal material of liquid metal interconnect 105 has a melting point of not more than 86° F. In some embodiments, the liquid metal material of liquid metal interconnect 105 has a melting point of not more than 80° F. In some embodiments, the liquid metal material of liquid metal interconnect 105 has a melting point of not more than 75° F. In some embodiments, the liquid metal material of liquid metal interconnect 105 has a melting point of not more than 72° F.

Liquid metal interconnects 105 may include any suitable material(s) having the discussed melting point characteristics. In some embodiments, liquid metal interconnects 105 include gallium such as a gallium alloy. Gallium-based liquid metals have a low melting point (e.g., below or near room temperature), low toxicity, low viscosity, and excellent electrical and thermal conductivity. As such, conductive pin 109 may be inserted into the gallium based liquid metal (i.e., liquid metal interconnect 105) to provide electrical coupling to an underlying pad (i.e., interconnect structure 102). In some embodiments, liquid metal interconnects 105 are a gallium based liquid metal, which may be alloyed with other elements such as tin, zinc, indium, or other metallic elements. In some embodiments, liquid metal interconnects 105 include approximately 80 atomic percent gallium or more, approximately 90 atomic percent gallium or more, or approximately 99 atomic percent gallium or more. As discussed, any moisture that penetrates into cavity 104 can cause oxidation of the liquid metal interconnects 105 that results in the formation of GaOOH crystals, which negatively impacts performance of liquid metal interconnects 105 and system 100. Although discussed with respect to gallium-based liquid metals, other base materials such as cesium-based liquid metals, rubidium-based liquid metals, or combinations of gallium-, cesium-, and rubidium-based material systems may be used. In some embodiments, liquid metal interconnect 105 includes gallium. In some embodiments, liquid metal interconnect 105 includes cesium. In some embodiments, liquid metal interconnect 105 includes rubidium.

Microelectronics board 101 may include any suitable electronic substrate such as a printed circuit board (PCB). Although discussed with respect to a board, any substrate such as an interposer, cored or coreless package substrate, or the like may be used. Interconnect structure 102 may be any suitable conductive material having any suitable form factor. For example, interconnect structure 102 may be copper pad formed on a dielectric material of microelectronics board 101. As shown, interconnect structure 102 on microelectronics board 101 is electrically coupled to package substrate 110 by conductive pin 109. Conductive pin 109 is electrically coupled to interconnect structure 102 through liquid metal interconnect 105. Liquid metal interconnect 105 is confined by confinement layer 103 that partially defines a cavity 104.

Confinement layer 103 may be any suitable insulating material such as a polymer (e.g., plastic), an oxide, or the like. Confinement layer 103 may be placed on microelectronics board 101 as a preform or confinement layer 103 may be built up on microelectronics board 101. As shown, the top of the cavity 104 is sealed by bilayer containment structure 106. Bilayer containment structure 106 may be pierced by conductive pin 109.

As shown, system 100, which may be characterized as an apparatus, includes confinement layer 103 over an electronic substrate (e.g., microelectronics board 101), such that confinement layer 103 defines cavity 104. System 100 further includes a liquid metal (e.g., liquid metal interconnect 105) within cavity 104 and a containment structure (e.g., bilayer containment structure 106) on confinement layer 103 and over cavity 104 (and further defining cavity 104). Bilayer containment structure 106 includes a porous polymeric material layer (e.g., porous material layer 107) and a self-healing material layer (e.g., self-healing material layer 108) on the porous polymeric material layer. In some embodiments, the porous polymeric material layer has an average pore size of not less than 1 nm and not more than 100 microns. In some embodiments, the porous polymeric material layer has an average pore size of not less than 5 nm and not more than 50 microns. In some embodiments, the porous polymeric material layer has an average pore size of not more than 25 microns. The self-healing material layer may include any suitable self-healing material system with metal oxide and metalloid oxides being particularly advantageous.

Porous material layer 107 is on confinement layer 103 and over cavity 104 to fully seal liquid metal interconnect 105 within cavity 104. Porous material layer 107 may be any suitable material or materials having the pore sizes discussed herein. In some embodiments, porous material layer 107 is or includes polyurethane (i.e., a polymeric material including carbon, oxygen, nitrogen, and hydrogen). In some embodiments, porous material layer 107 is or includes polyimide (i.e., a polymeric material including carbon, oxygen, nitrogen, and hydrogen). In some embodiments, porous material layer 107 is or includes polyethylene (i.e., a polymeric material including carbon and hydrogen). In some embodiments, porous material layer 107 is or includes polyethylene and silicone (i.e., a polymeric material including carbon, oxygen, silicon, and hydrogen). In some embodiments, porous material layer 107 is or includes polypropylene (i.e., a polymeric material including carbon and hydrogen). In some embodiments, porous material layer 107 is or includes polystyrene (i.e., a polymeric material including carbon and hydrogen). In some embodiments, porous material layer 107 is or includes polyvinyl chloride (i.e., a polymeric material including carbon, chlorine, and hydrogen). In some embodiments, porous material layer 107 is or includes a polymer. In some embodiments, porous material layer 107 is a porous polymeric material layer. As used herein, the term polymer or polymeric material indicates a material having large molecules (macromolecules), typically having carbon chain backbones, composed of repeating subunits.

Self-healing material layer 108 is on porous material layer 107 and over cavity 104 to support the full seal of liquid metal interconnect 105 within cavity 104 and to provide self-healing for bilayer containment structure 106 due to removal of conductive pin 109 and/or other damage to bilayer containment structure 106. Self-healing material layer 108 may be any suitable material or materials having self-healing characteristics. In some embodiments, self-healing material layer 108 includes a metal oxide or metalloid oxide within a gel material. In some embodiments, self-healing material layer 108 includes a metal oxide or metalloid oxide dispersed in a gel or gel-type adhesive. In some embodiments, self-healing material layer 108 includes metal oxide or metalloid oxide particles surrounded by a gel or gel-type adhesive and dispersed in an epoxy. In some embodiments, the gel or gel-type adhesive is an acrylic adhesive such as 2, 4, 7, 9-tetramethyldec-5-yne-4,7-diol. Self-healing material layer 108 of system 100 may have any suitable thickness such as a thickness in the range of 10 to 50 microns. In some embodiments, self-healing material layer 108 has a thickness of not less than 10 microns and not more than 50 microns. In some embodiments, self-healing material layer 108 has a thickness of not less than 10 microns and not more than 25 microns. In some embodiments, self-healing material layer 108 has a thickness of not less than 25 microns and not more than 50 microns. However, other thicknesses may be used.

In some embodiments, the metal oxide or metalloid oxide includes one or more of titanium oxide, cerium dioxide, silica, magnetite, zirconia, graphene oxide, alumina, or talc nanoparticles. In some embodiments, self-healing material layer 108 includes titanium oxide (e.g., includes oxygen and titanium). Titanium oxide has advantages such as manufacturability and good self-healing characteristics. In some embodiments, self-healing material layer 108 includes cerium dioxide (e.g., includes oxygen and cerium). In some embodiments, self-healing material layer 108 includes silica (e.g., includes oxygen and silicon). In some embodiments, self-healing material layer 108 includes magnetite (e.g., includes oxygen and iron). In some embodiments, self-healing material layer 108 includes zirconia (e.g., includes oxygen and zirconium). In some embodiments, self-healing material layer 108 includes graphene oxide (e.g., includes oxygen and graphene; e.g., oxygen and carbon). In some embodiments, self-healing material layer 108 includes alumina (e.g., includes oxygen and aluminum). In some embodiments, self-healing material layer 108 includes talc particles (e.g., includes oxygen, silicon, and magnesium). The particles of the metal oxide or metalloid oxide may have any suitable size and shape. In some embodiments, the particles of the metal oxide or metalloid oxide are nanospheres having a particle size in the range of 100 to 200 nm. Although discussed with respect to metal oxide nanoparticles, other self-healing materials using other self-healing mechanisms can be used such as releasable self-healing agents, reversible bonding self-healing, vascular self-healing, shape memory self-healing, intrinsic self-healing polymers, and the like.

In some embodiments, the metal oxide or metalloid oxide is dispersed within an epoxy material, a gel material, or other polymeric material. Notably, the matrix material may have pore size as discussed with respect to porous material layer 107 or greater. In some embodiments, self-healing material layer 108 has pores or openings larger than those of self-healing material layer 108. For example, self-healing material layer 108 may have any pore size discussed with respect to porous material layer 107 or greater. In some embodiments, a ratio of the pore size of self-healing material layer 108 to the pore size of porous material layer 107 is not less than one. In some embodiments, a ratio of the pore size of self-healing material layer 108 to the pore size of porous material layer 107 is not less than 1.5. In some embodiments, a ratio of the pore size of self-healing material layer 108 to the pore size of porous material layer 107 is not less than two. In some embodiments, a ratio of the pore size of self-healing material layer 108 to the pore size of porous material layer 107 is not less than ten. Other ratios may be used.

As discussed, porous material layer 107 and self-healing material layer 108 seal cavity 104 to block ingress of moisture while allowing ventilation of hydrogen.

FIG. 2 illustrates a cross-sectional side view of example system 100 and mechanisms 200 for preventing moisture and venting hydrogen, arranged in accordance with at least some implementations of the present disclosure. For example, FIG. 2 illustrates mechanisms 200 for preventing moisture and venting hydrogen from cavity 104 of system 100. In FIG. 2, conductive pin 109 and package substrate 110 are not illustrated for the sake of clarity of presentation. It is noted mechanisms 200 are evident when conductive pin 109 and package substrate 110 are deployed. As shown in FIG. 2, in some contexts, system 100 is in conditions where heat and moisture 201 are in the environment surrounding system 100. For example, system 100 is expected to operate fully under high temperature, high humidity conditions (e.g., with testing at relative humidity of 85% and temperature of 85° C.).

Also as shown, bilayer containment structure 106 blocks moisture 203 due to the presence of porous material layer 107 as aided in part by self-healing material layer 108. Furthermore, bilayer containment structure 106 vents hydrogen 202 from cavity 104. Such mechanisms 200 are provided by the materials and structures discussed herein with respect to porous material layer 107 and self-healing material layer 108. In some embodiments, moisture blocking and hydrogen venting are provided mainly by porous material layer 107 of bilayer containment structure 106, as shown with respect to inserts 211, 212, 213, 214. Inserts 211, 213 illustrates blocking of moisture 203 from cavity 104 due to pore size 222 of porous material layer 107 being relatively small in comparison to moisture 221 or water molecules, which can present as water droplets and/or be bound to other atmospheric components. Inserts 212, 214 illustrates venting of hydrogen 202 due to pore size 222 of porous material layer 107 being relatively large in comparison to hydrogen molecules 223. As discussed herein, pore size 222 of porous material layer 107 (e.g., the size of micropores) can be controlled or adjusted at the nano or micron unit level to provide for the discussed selective hydrogen gas permeability and moisture permeability.

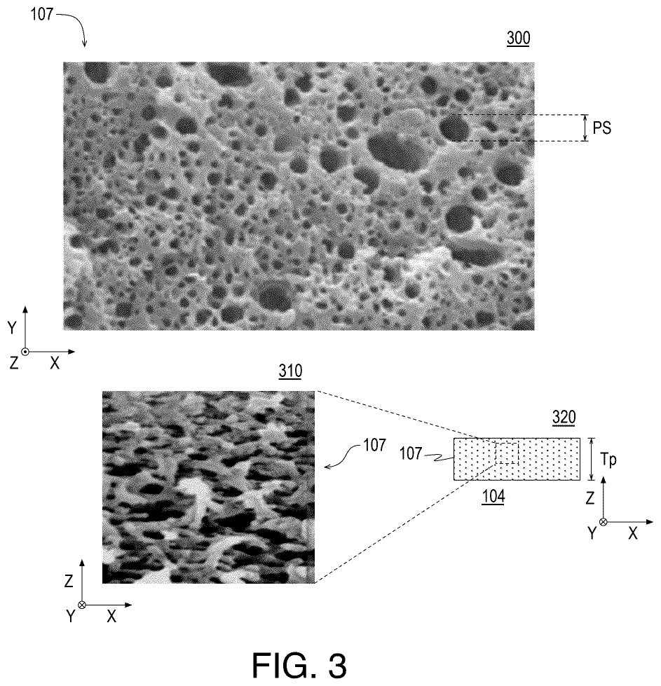

FIG. 3 illustrates exemplary characteristics of porous material layer 107 including a top-down view 300, a cross-sectional side view 310, and thickness characteristics 320, arranged in accordance with at least some implementations of the present disclosure. As shown in FIG. 3, porous material layer 107 has a characteristic pore size (PS), which may be in the ranges discussed herein such as a pore size (PS) of not less than 1 nm and not more than 100 microns, not less than 5 nm and not more than 50 microns, not more than 25 microns, or the like. The characteristic pore size may be determined using any suitable technique or techniques. In some embodiments, a surface or cross-section of porous material layer 107 is analyzed, a number of pores are measured, and an average of the measurements is determined. The surface or cross-section of porous material layer 107 may be taken at any suitable location or plane such as at a top surface of porous material layer 107. Any number of pores may be measured such as not fewer than 10, not fewer than 20, not fewer than 50, not fewer than 100, or more. Such measurements may discard a certain percentage of high and low measurements (i.e., 5-10% of the measurements may be discarded or those outside of a range of the average may be discarded or the like). The measurement of each pore may be the greatest width of the pore, the median width of the pore, or the like. In some embodiments, a top surface of porous material layer 107 is analyzed, not fewer than 10 pores are measured to determine their greatest width, and the average of the pore widths is the characteristic pore size (PS) of porous material layer 107. Notably, porous material layer 107 (e.g., the membrane of porous material layer 107 contains pores that are sufficiently small to be completely waterproof and resistant to liquids, yet large enough to permit the passage of any gas, including hydrogen. In some embodiments, each of the potentially billions or more of pores are smaller than a water vapor molecule to prevent moisture ingress.

FIG. 3 also illustrates a cross-sectional side view 310 of an example porous material layer 107, which shows the pores extending through porous material layer 107 along a number of routes. For example, the pores of porous material layer 107 do not extend vertically but instead meander or take a tortious route through porous material layer 107 as is known in the art. FIG. 3 further shows thickness characteristics 320 of porous material layer 107. Porous material layer 107 of system 100 may have any suitable thickness Tp such as a thickness Tp in the range of 10 to 50 microns. In some embodiments, porous material layer 107 has a thickness Tp of not less than 10 microns and not more than 50 microns. In some embodiments, porous material layer 107 has a thickness Tp of not less than 10 microns and not more than 25 microns. In some embodiments, porous material layer 107 has a thickness Tp of not less than 25 microns and not more than 50 microns. However, other thicknesses may be used.

Returning to FIG. 1, as discussed, porous material layer 107 and self-healing material layer 108 of bilayer containment structure 106 encapsulate cavity 104 and therefore liquid metal interconnect 105. Bilayer containment structure 106 (e.g., a gas-permeable membrane cap layer) facilitates the efficient release of gases, maintaining internal pressure and preventing moisture ingress into cavity 104. This reduces or eliminates detachment of bilayer containment structure 106 from confinement layer 103 for improved long-term reliability of system 100. This gas release while also filtering moisture and other contaminants.

Furthermore, self-healing material layer 108 aids in prevention of in-situ permanent damage to bilayer containment structure 106 as well as repair of bilayer containment structure 106 after removal of conductive pin 109.

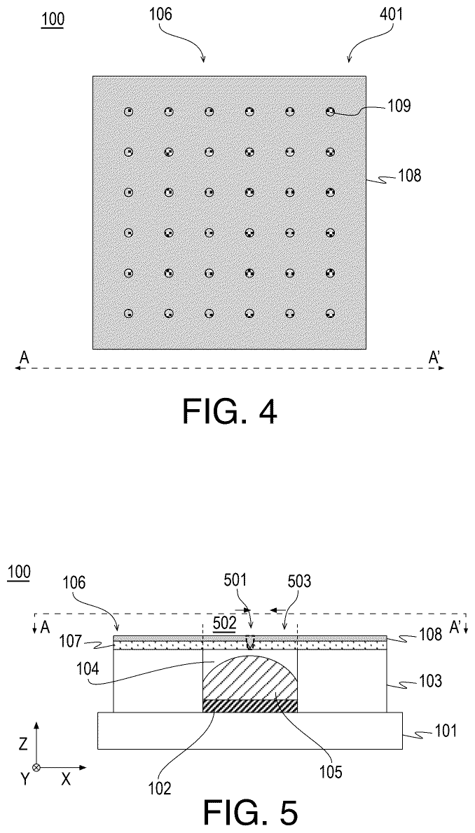

FIG. 4 provides a cross-sectional top-down view 401 of system 100 to illustrate an example layout of conductive pins 109 penetrating bilayer containment structure 106, arranged in accordance with at least some implementations of the present disclosure. With reference to FIG. 1, cross-sectional top-down view 401 is taken at the illustrated A-A′ plane. As shown, in some embodiments, conductive pins 109 are arranged in a grid pattern and extend through both self-healing material layer 108 (as shown) and porous material layer 107 (underlying self-healing material layer 108) of bilayer containment structure 106. It is noted openings of confinement layer 103 and interconnect structures 102 of microelectronics board 101 are provided in the same pattern as the layout of conductive pins 109. As discussed, it may be advantageous to remove conductive pins 109 and package substrate 110 such that the same or different component may be later coupled to microelectronics board 101. For example, a part may be swapped out due to failure or for an upgrade or the like. Self-healing material layer 108 facilitates swap out procedures by healing bilayer containment structure 106 after the removal of conductive pins 109.

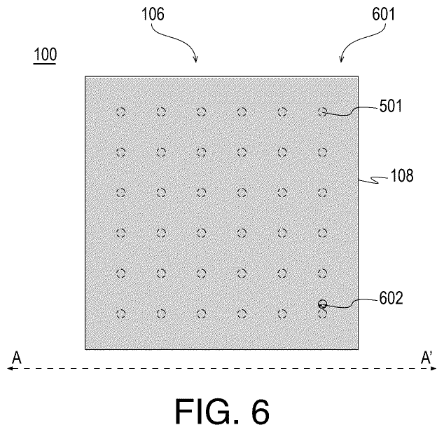

FIG. 5 illustrates a cross-sectional side view of example system 100 after removal of conductive pin 109 and self-healing of bilayer containment structure 106, arranged in accordance with at least some implementations of the present disclosure. FIG. 6 provides a cross-sectional top-down view 601 of system 100 to illustrate exemplary self-healing bilayer containment structure, arranged in accordance with at least some implementations of the present disclosure. With reference to FIG. 5, after self-healing 502 as provided by the chemistry of self-healing material layer 108, a region 501 of bilayer containment structure 106 has self-healed to again encapsulate cavity 104 and to protect liquid metal interconnect 105 from moisture while allowing ventilation of hydrogen as discussed herein. It is noted that region 501 may heal in a manner that closes pores and entirely seals bilayer containment structure 106 from the incursion of moisture and ventilation of hydrogen in region 501. However, region 503 of bilayer containment structure 106 allow for ventilation of hydrogen. For example, region 503 of bilayer containment structure 106 is the region over cavity 104 and outside of region 501. Due not undergoing self-healing, such regions may allow for greater ventilation of hydrogen relative that of region 501 in some embodiments. The mechanism of self-healing of bilayer containment structure 106 is discussed herein below.

With reference to FIG. 6, as shown, each of regions 501 are self-healed in the grid pattern discussed with respect to FIG. 4 and the underlying cavities 104 and liquid metal interconnects 105 therein are protected from moisture while allowing for hydrogen ventilation. Subsequently, conductive pins 109 are again contacted to liquid metal interconnects 105. Such connections may be made directly through regions 501 such that previous and subsequent penetration of bilayer containment structure 106 are made at the same locations or they may be offset while still contacting liquid metal interconnects 105. In some embodiments, subsequent conductive pins extends through bilayer containment structure 106 at a location outside of self-healed region 501 such that a non-healed region is laterally between the conductive pin and self-healed region 501, as shown with respect to subsequent pin location 602.

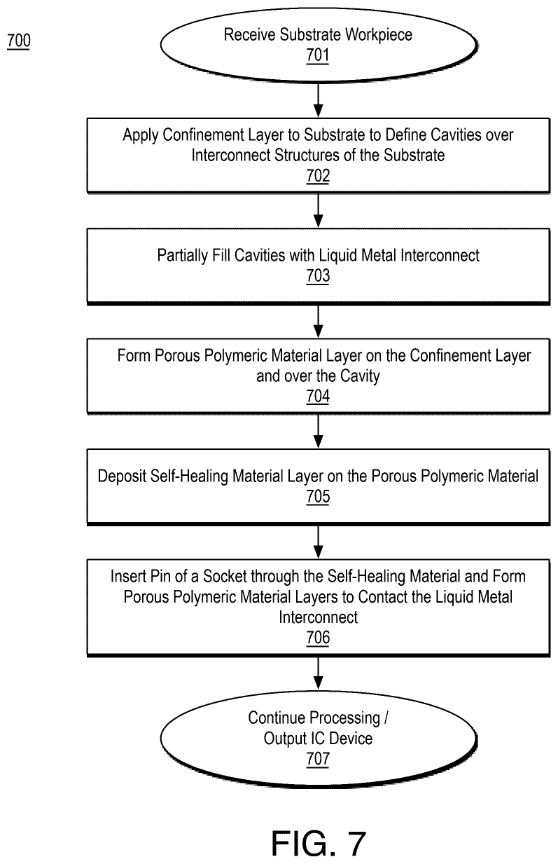

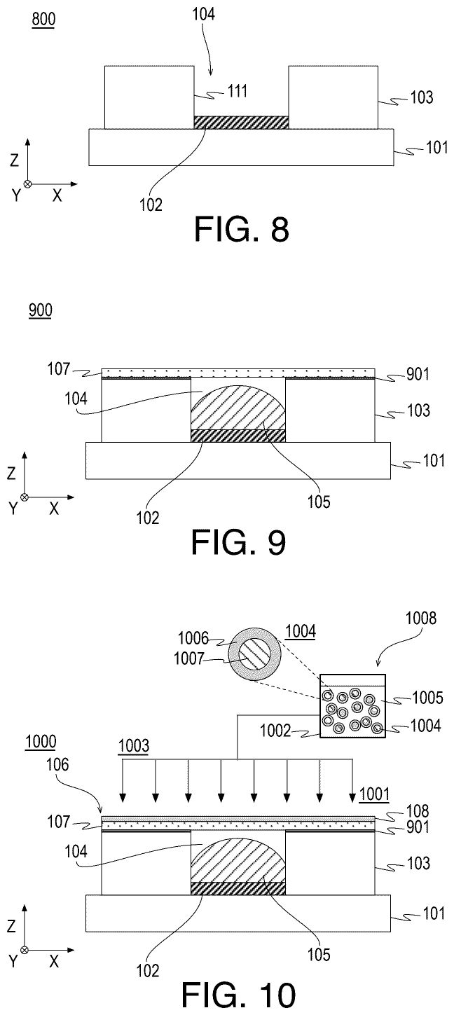

FIG. 7 is a flow diagram illustrating an example process 700 for fabricating and assembling integrated circuit devices having a liquid metal interconnect encapsulated within a cavity covered by a bilayer containment structure having a porous material layer and a self-healing material layer, arranged in accordance with at least some implementations of the present disclosure. For example, process 700 may be implemented to fabricate systems, apparatuses, or device structures illustrated in FIGS. 8-16 or elsewhere herein. FIGS. 8, 9, 10, 11, 12, 13, 14, 15, and 16 illustrate example integrated circuit device structures as the operations of process 700 are performed, arranged in accordance with at least some implementations of the present disclosure.

Process 700 begins at operation 701, where a workpiece such as an electronics board or other electronics substrate having exposed interconnect structures is received for processing. In some embodiments, the electronics board or other electronics substrate includes an array or grid of exposed contact pads such as copper pads that interconnect to circuitry within the electronics board or other electronics substrate. For example, the electronics board or other electronics substrate may include metallization to interconnect devices mounted to the electronics board or other electronics substrate. The interconnect structures of the electronics board or other electronics substrate may be any level of interconnects such as first level interconnect (FLI), second level interconnect (SLI), or higher-level interconnects, in any suitable system context.

Processing continues at operation 702, where a confinement layer is applied on or over a top surface of the electronics board or other electronics substrate such that openings in the confinement layer expose the interconnects of the top surface of the electronics board or other electronics substrate and define a cavity around the interconnects. The confinement layer may be formed using any suitable technique or techniques. In some embodiments, the confinement layer is a preformed plastic patterned layer that is adhered to the top surface of the electronics board or other electronics substrate using an adhesive such as an epoxy. In some embodiments, the confinement layer is built-up on or over the top surface of the electronics board or other electronics substrate and subsequently patterned to form the openings. In some embodiments, the confinement layer on or over the electronics board or other electronics substrate are received for processing with the confinement layer already attached to the electronics board or other electronics substrate and defining cavities over the interconnects of the electronics board or other electronics substrate.

FIG. 8 illustrates example integrated circuit device structure or system 800 after confinement layer 103 is attached to microelectronics board 101 to define sidewall 111 of cavity 104 that exposes interconnect structures 102. As discussed, confinement layer 103 may be formed or applied using any suitable technique or techniques such as attaching plastic patterned layer or patch to the top surface of microelectronics board 101 using an adhesive building up a bulk layer and patterning the bulk layer to form confinement layer 103, or the like.

Returning to FIG. 7, processing continues at operation 703, where the cavities over the exposed interconnects of the top surface of the electronics board or other electronics substrate are partially filled with liquid metal. The liquid metal may be deposited in the cavities and directly onto the exposed interconnects using any suitable technique or techniques such as dispensing the liquid metal using a dispensing tool having a nozzle and associated piping, pressure and flow control systems, etc. For example, the dispensing tool may move over the electronics board or other electronics substrate (or the electronics board or other electronics substrate may move under the dispensing tool) to align the tool with each cavity and the pertinent volume of liquid metal may be dispensed into the cavity.

Processing continues at operation 704, where a porous polymeric material layer is formed on the confinement layer and over the cavity to seal the liquid metal deposited at operation 703 within the cavity defined at operation 702. Any porous polymeric material layer discussed herein may be deployed at operation 704. In some embodiments, the porous polymeric material layer has an average pore size of not less than 1 nm and not more than 100 microns. In some embodiments, the porous polymeric material layer is polyurethane, polyimide, polyethylene, or a combination thereof. The porous polymeric material layer may be formed on the confinement layer and over the cavity using any suitable technique or techniques. In some embodiments, forming the porous polymeric material layer on the confinement layer and over the cavity includes receiving the porous polymeric material layer as a preform and adhering the preform to the confinement layer. For example, the preform may be attached to the confinement layer using an adhesive. In some embodiments, forming the porous polymeric material layer on the confinement layer and over the cavity includes building up the porous polymeric material layer on the confinement layer using material deposition techniques.

FIG. 9 illustrates example integrated circuit device structure or system 900 similar to integrated circuit device structure or system 800 after depositing liquid metal interconnect 105 encapsulated within cavity 104 and forming porous material layer 107 on confinement layer 103 and over cavity 104 to further define cavity 104 and to seal liquid metal interconnect 105 within cavity 104. Liquid metal interconnect 105 may have any characteristics discussed herein and liquid metal interconnect 105 may be deposited within cavity 104 using a dispensing tool or the like. In some embodiments, liquid metal interconnect 105 is a gallium based liquid metal, which may be alloyed with other metals.

Porous material layer 107 may have any characteristics discussed herein. Porous material layer 107 may be formed on confinement layer 103 by, for example, receiving porous material layer 107 as a preform and adhering the preform to confinement layer 103, building up porous material layer 107 on confinement layer 103 using material deposition techniques, or the like. In the illustrated example, porous material layer 107 is attached to confinement layer 103 using adhesive 901. Adhesive 901 may be any suitable material such as an epoxy. As shown, adhesive 901 is between porous material layer 107 and confinement layer 103. In some embodiments, adhesive 901 is directly on porous material layer 107 and confinement layer 103.

Returning to FIG. 7, processing continues at operation 705, where a self-healing material layer is deposited directly on the porous polymeric material layer and over the cavity to further seal the liquid metal deposited at operation 703 within the cavity defined at operation 702, and to provide a self-healing capability to the resultant bilayer structure. Any self-healing material discussed herein may be deployed at operation 705. In some embodiments, the self-healing material such as a metal oxide, a metalloid oxide, a gel adhesive, or an epoxy resin. The self-healing material layer may be formed on the porous polymeric material layer using any suitable technique or techniques. In some embodiments, depositing the self-healing material layer includes spray coating the self-healing material layer on the porous polymeric material layer. In some embodiments, depositing the self-healing material layer includes brushing the self-healing material layer on the porous polymeric material layer.

FIG. 10 illustrates example integrated circuit device structure or system 1000 similar to integrated circuit device structure or system 900 during deposition of self-healing material layer 108 on porous material layer 107. In the illustrated example, a spray coating operation 1001 using nozzles 1003 is performed to deposit self-healing material layer 108. For example, nozzles 1003 (and associated piping, pressure and flow control systems, etc.) may be used to dispense self-healing material layer 108 from a container 1002. However, other techniques such as brush coating the self-healing material layer onto the porous polymeric material layer may be used.

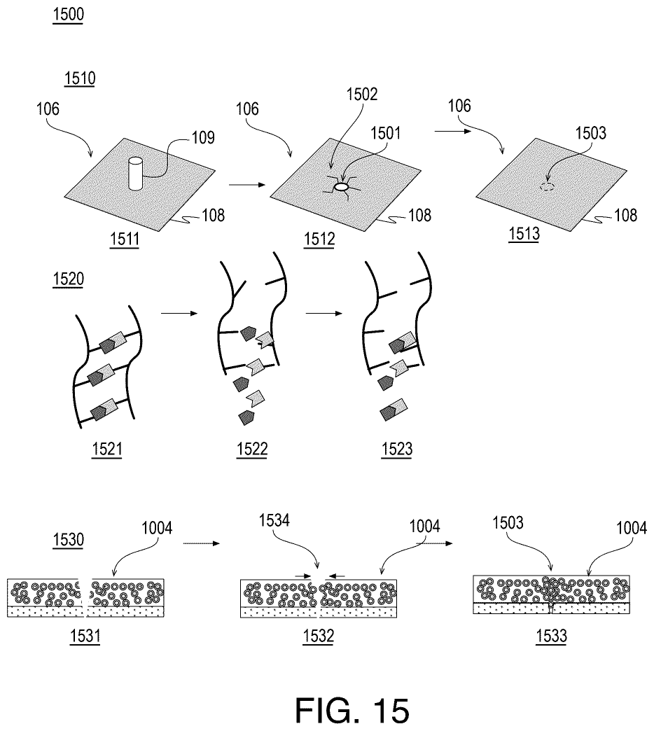

As shown, in some embodiments, a self-healing solution 1008 is prepared. In some embodiments, self-healing particles 1004 include a metal or metalloid oxide 1007 encapsulated by gel-type adhesive 1006, and self-healing particles 1004 are dispersed in an epoxy resin 1005. In some embodiments, gel-type adhesive 1006 is an acrylic adhesive such as 2, 4, 7, 9-tetramethyldec-5-yne-4,7-diol. In some embodiments, gel-type adhesive 1006 reacts with hydroxyl groups on the surfaces of metal or metalloid oxide 1007 (e.g., nanoparticles) to form a covalent bond, leading to a polymeric shell surrounding metal or metalloid oxide nanoparticles. As described with respect to FIG. 15, these covalent bonds are capable of exchanging, dissociating, or switching in response to various stimuli

In some embodiments, self-healing particles 1004 employ a core-shell nanogel composite structure. Self-healing solution 1008 is then spray coated (as shown) or brush-coated onto porous material layer 107. Self-healing solution 1008 may then be cured to form self-healing material layer 108. In some embodiments, self-healing solution 1008 is cured at room temperature.

In some embodiments, directly application of self-healing material layer 108 (e.g., self-healing solution 1008) onto porous material layer 107 (e.g., a gas-permeable cap layer) prevents in-situ permanent damage, which increases long-term reliability of bilayer containment structure 106. As discussed, porous material layer 107 allows passage of gas (i.e., hydrogen) while preventing moisture ingress during device operation. Applying self-healing material layer 108 to porous material layer 107 ensures no interference with electrical performance while the overall thickness of bilayer containment structure 106 is kept minimal, resulting in low pin insertion force. Furthermore, self-healing material layer 108 facilitates rapid reconstruction of the original shape of the punctured hole, providing added resilience to the structure. The self-healable solution can cure at room temperature, allowing integration into the liquid metal dispense manufacturing process without the need for additional heating, advantageously resulting in a cost-effective and fully integrated solution. During operation, the resultant bilayer containment structure 106 addresses expansion issues of liquid metal interconnect 105, maintains pressure equilibrium between cavity 104 and the outside world, minimizes condensation within cavity 104, and averts damage to the capping layer (i.e., bilayer containment structure 106) over cavity 104.

The discussed characteristics of bilayer containment structure 106 may be analyzed and detected using any suitable technique or techniques such as scanning electron microscopy (to determine cross-sections of porous material layer 107, pore sizes, pore density, and material layer thicknesses as well as synthesized core-shell nanogel composite morphology, size, and distribution), energy dispersive x-ray spectroscopy (to examine chemical composition of bilayer containment structure 106), x-ray photoelectron spectroscopy (to determine quantitative and chemical state information from the surfaces of bilayer containment structure 106), x-ray diffraction spectroscopy (to detect metal oxide particles), Fourier transform infrared spectroscopy (to determine material identification and quantification), and others.

In some embodiments, self-healing material layer 108 is applied to an entire surface of porous material layer 107. However, in some embodiments, self-healing material layer 108 may be applied only to those regions of porous material layer 107 that are over cavity 104.

FIG. 11 illustrates example integrated circuit device structure or system 1100 similar to integrated circuit device structure or system 900 during deposition of self-healing material layer 108 onto selected regions of porous material layer 107. In the illustrated embodiment, selective spray coating operation 1101 using nozzles 1003 is performed to selectively deposit self-healing material layer 108 on regions 1103 while regions 1102 are absent self-healing material layer 108. For example, porous material layer 107 has region 1103 over cavity 104 and region 1102 outside of cavity 104. In the context of integrated circuit device structure or system 1100, self-healing material layer 108 is on region 1103 and absent from region 1102. Such embodiments may reduce cost and increase processing efficiency with respect to application of self-healing material layer 108.

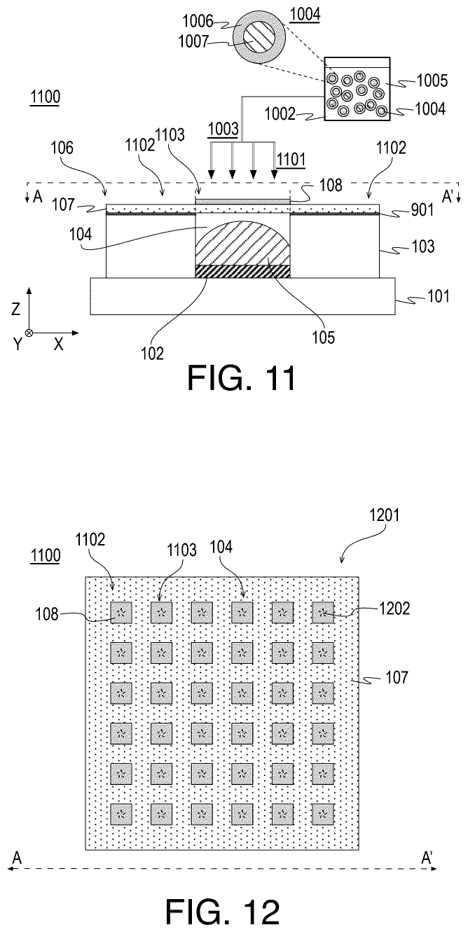

FIG. 12 provides a top-down view 1201 of integrated circuit device structure or system 1100 to illustrate an example layout of regions 1103 and corresponding cavities 104. As shown, regions 1103 include self-healing material layer 108 while regions 1102 are absent self-healing material layer 108. In the context of integrated circuit device structure or system 1100, self-healing capability is provided at conductive pin locations 1202 (i.e., locations where conductive pins will puncture into underlying cavities 104) but not at other locations of porous material layer 107.

Returning to FIG. 7, processing continues at operation 706, where the bilayer formed at operations 704, 705 is punctured at various locations by conductive pins (e.g., socket pins) to contact the encapsulated liquid metal interconnects deposited at operation 703. The conductive pins then interface with the encapsulated liquid metal to form conductive routes for the resultant system such as conductive routes from a microelectronics board to a microelectronics package. The conductive pins may be contacted to the encapsulated liquid metal using any suitable technique or techniques such as socket connect techniques. It is noted the microelectronics package and conductive pins may then be removed and re-installed or replaced with another microelectronics package any number of times with the self-healing material layer of the bilayer capping structure mitigating damage due to the puncture from the conductive pins.

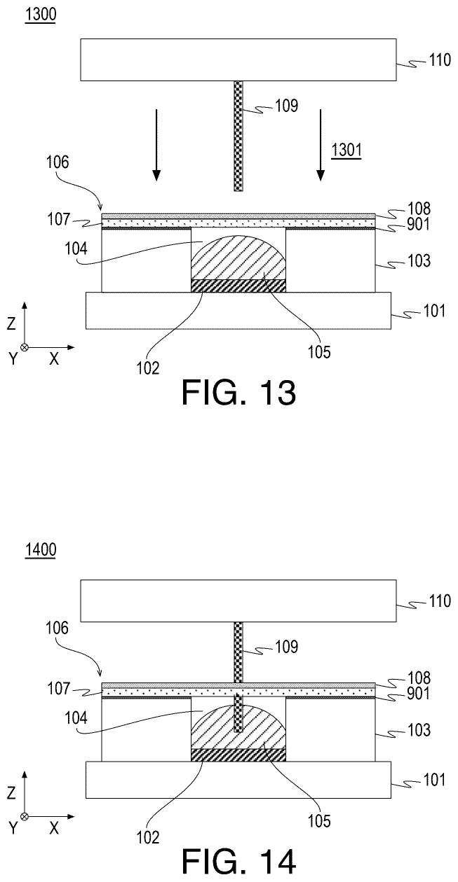

FIG. 13 illustrates example integrated circuit device structure or system 1300 similar to integrated circuit device structure or system 1100 during socket connect operation 1301 that aligns conductive pins 109 to liquid metal interconnects 105 applies a downward force to puncture bilayer containment structure 106 using conductive pins 109. Such socket alignment and connection may be made using any suitable technique or techniques.

FIG. 14 illustrates example integrated circuit device structure or system 1400 similar to integrated circuit device structure or system 1300 after socket connect operation 1301 brings conductive pins 109 into contact with liquid metal interconnects 105. Notably, integrated circuit device structure or system 1400 is similar to system 100. The discussed techniques and structures avert moisture ingress (to reduce or eliminate undesirable formation of GaOOH crystallites), secure the seal of cavity 104, and avoid contamination within the LM socket. In some embodiments, porous material layer 107 is a flexible membrane with an adequate number of pores of suitable sizes, which facilitates the passage of gas molecules (e.g., approximately 0.3 nm in diameter) while blocking water droplets (e.g., around 100 μm in diameter) across the permeable membrane. Furthermore, self-healing material layer 108 reduces or eliminates minor damage, increasing reliability, product lifetime, and improving environmental sustainability.

As discussed, conductive pins 109 may be removed and self-healing material layer 108 may heal bilayer containment structure 106. Furthermore, other damage to bilayer containment structure 106 may be healed by self-healing material layer 108. Such self-healing may be realized using any suitable mechanisms.

FIG. 15 illustrates an example integrated circuit device structure or system 1500 showing exemplary self-healing mechanisms. As shown with respect to progression 1510, in some embodiments, conductive pin 109 punctures bilayer containment structure 106 at stage 1511. At stage 1512, conductive pin 109 is removed from bilayer containment structure 106, leaving a hole 1501 and, in some cases, cracks 1502. At stage 1513, hole 1501 cracks 1502 are self-healed to form a self-healed region 1503.

In some embodiments, such self-healing is through a reconfigurable covalent bonding processing as shown with respect to progression 1520. For example, as shown with respect to the transition from stage 1521 to stage 1522, covalent bonds may be broken when bilayer containment structure 106 is punctured, damaged, conductive pin 109 is removed, or the like. Some of such covalent bonds may be self-healed as shown with respect to the transition from stage 1522 to stage 1523 to form self-healed region 1503. In some embodiments, the self-healing is provided by self-healing particles 1004 (refer to FIG. 10), which may be characterized as microcapsules or nano-capsules. As shown with respect to progression 1530, in the event of damage as shown at stage 1531, self-healing particles 1004 (e.g., microcapsules or nano-capsules) within self-healing material layer 108 are broken, moving and releasing 1534 a healing agent (e.g., metal or metalloid oxide nanoparticles) that polymerizes at the spot of damage as shown in stage 1532. This autonomous process offers immediate response and protection, mitigates corrosion, and maximizes coating performance. For example, the reversible covalent bonds (see progression 1520) illustrate the breaking and formation of bonds as part of the polymerization at the spot of damage. Once the coating on the surface has a defect as shown at stage 1531, the particles and are released toward the defect as shown at stage 1532 and ultimately form a capping of the defect to provide self-healed region 1503 as shown at stage 1533.

With reference to FIG. 10, in some embodiments, a flexible polymeric layer (e.g., gel-type adhesive 1006) is on a surface of core-shell nanoparticles (e.g., metal or metalloid oxide 1007) and enhances their dispersion in epoxy resin 1005. The employed polymeric adhesive gel provides a segmental motion to heal the damaged areas. For example, the polymeric adhesive gel may be 2, 4, 7, 9-tetramethyldec-5-yne-4,7-diol, but other gel type adhesives may be used. The polymeric adhesive gel assists in the formation of a homogeneous interfacial layer over the metal or metalloid oxide particle, reacting with hydroxyl groups on surfaces of metal or metalloid oxide particle to form a covalent bond, leading to a polymeric shell surrounding the metal or metalloid oxide particle. As described with respect to FIG. 15, the covalent bonds exchange, dissociate, or switch to provide self-healing. For example, the core shell structure may be is mixed with an epoxy resin, and the main chemical chains may be crosslinked either by different functional groups or by additional free linker molecules to form a self-healable network. As illustrated in FIG. 15, if defects appear on the coatings, the core-shell structure fills the defects, which autonomously heal. For example, this mechanism may be based on the migration of the nanoparticles and its swelling property, such that nanoparticles fill up the micro-cracks present in the coating, leading to lower free volume, which serves as a protective barrier and causes considerable resilience and durability of the coating properties.

Returning to FIG. 7, processing continues at operation 707, where the assembled integrated circuit system may be further processed and output to provide an integrated circuit system or device. For example, the resultant assembly may be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

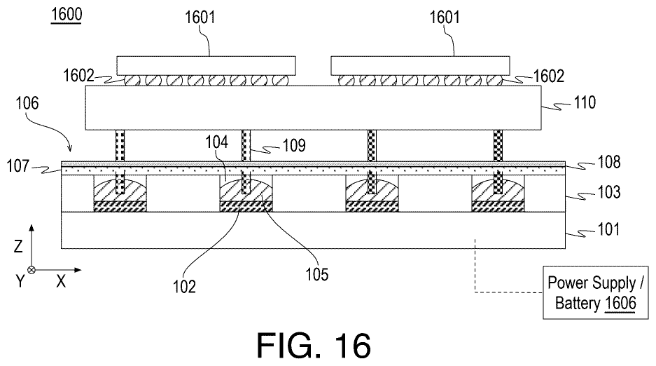

FIG. 16 illustrates an example integrated circuit device structure or system 1600 having a number of integrated circuit dies 1601 coupled to package substrate 110 to form an assembled apparatus or system. As shown, in an embodiment, microelectronics board 101 is coupled to package substrate 110 with a socket architecture. As discussed, confinement layer 103 over microelectronics board 101 includes cavities 104 over interconnect structures 102 of microelectronics board 101. Liquid metal interconnects 105 are on interconnect structures 102 and within cavities 104. Bilayer containment structure 106 is on confinement layer 103 and over cavities 104 to encapsulate liquid metal interconnects 105. Bilayer containment structure 106 includes porous material layer 107 and self-healing material layer 108, which may have any characteristics discussed herein. Conductive pins 109 penetrate bilayer containment structure 106 and contact liquid metal interconnects 105. Thereby, conductive pins 109, liquid metal interconnects 105, and interconnect structures 102 are at least a part of an electric coupling between microelectronics board 101 and package substrate 110.

Any number of IC dies 1601 are coupled to package substrate 110 by interconnects 1602. Interconnects 1602 may include any suitable interconnect technology. For example, interconnects 1602 may include solder, copper bumps, or any other FLI architecture such as and FLI architecture. IC dies 1601 may include any type of integrated circuit device such as those discussed herein below. In some embodiments, IC dies 1601 include a central processing unit (CPU), a graphics processing unit (GPU), an XPU, a system on a chip (SoC), a communications die, or a memory. As shown, in some embodiments, microelectronics board 101 (or another component of system 1600) is coupled to a power supply 1606. Power supply 1606 may include a battery, voltage converter, power supply circuitry, or the like. For example, system 1600 includes one or more IC dies 1601 attached to package substrate 110, and conductive pins 109 (e.g., socket interconnects) coupling package substrate 110 to microelectronics board 101 such that conductive pins 109 extend through bilayer containment structure 106.

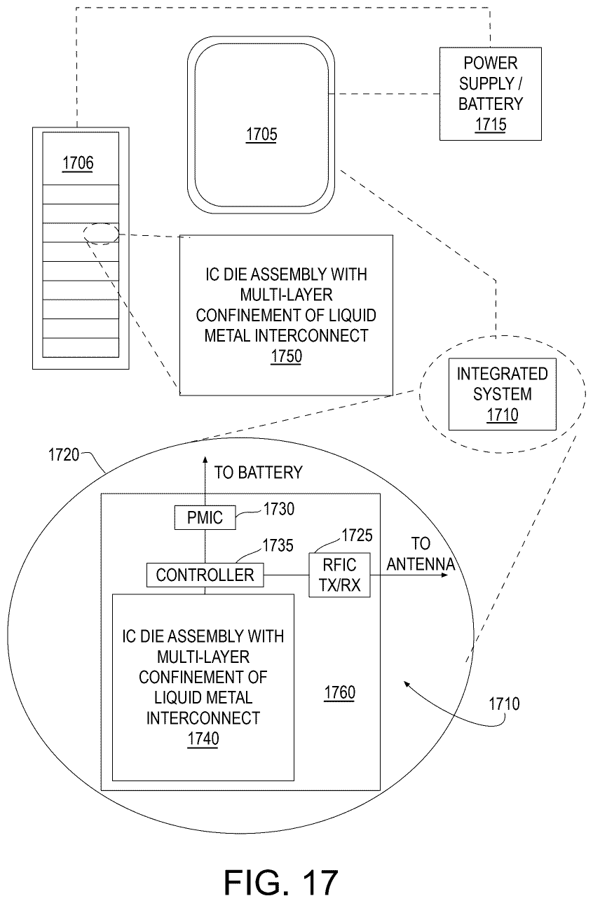

FIG. 17 illustrates exemplary systems employing an assembly including a liquid metal interconnect encapsulated within a cavity covered by a bilayer containment structure having a porous material layer and a self-healing material layer, in accordance with some embodiments. The system may be a mobile computing platform 1705 and/or a data server machine 1706, for example. Either may employ an assembly including a liquid metal interconnect encapsulated within a cavity covered by a bilayer containment structure having a porous material layer and a self-healing material layer as described elsewhere herein. Data server machine 1706 may be any commercial server, for example including any number of high-performance computing platforms disposed within a rack and networked together for electronic data processing, which in the exemplary embodiment includes an IC die assembly 1750 with an assembly including a liquid metal interconnect encapsulated within a cavity covered by a bilayer containment structure having a porous material layer and a self-healing material layer as described elsewhere herein. Mobile computing platform 1705 may be any portable device configured for each of electronic data display, electronic data processing, wireless electronic data transmission, or the like. For example, mobile computing platform 1705 may be any of a tablet, a laptop computer, etc., and may include a display screen (e.g., a capacitive, inductive, resistive, or optical touchscreen), a chip-level or package-level integrated system 1710, and a battery 1715. Although illustrated with respect to mobile computing platform 1705, in other examples, chip-level or package-level integrated system 1710 and a battery 1715 may be implemented in a desktop computing platform, an automotive computing platform, an internet of things platform, or the like. As discussed below, in some examples, the disclosed systems may include a sub-system 1760 such as a system on a chip (SOC) or an integrated system of multiple ICs, which is illustrated with respect to mobile computing platform 1705.

Whether disposed within integrated system 1710 illustrated in expanded view 1720 or as a stand-alone packaged device within data server machine 1706, sub-system 1760 may include memory circuitry and/or processor circuitry 1740 (e.g., RAM, a microprocessor, a multi-core microprocessor, graphics processor, etc.), a power management integrated circuit (PMIC) 1730, a controller 1735, and a radio frequency integrated circuit (RFIC) 1725 (e.g., including a wideband RF transmitter and/or receiver (TX/RX)). As shown, one or more IC dice, such as memory circuitry and/or processor circuitry 1740 may be assembled and implemented such that one or more are incorporated in a system having an assembly including a liquid metal interconnect encapsulated within a cavity covered by a bilayer containment structure having a porous material layer and a self-healing material layer as described herein. In some embodiments, RFIC 1725 includes a digital baseband and an analog front end module further comprising a power amplifier on a transmit path and a low noise amplifier on a receive path). Functionally, PMIC 1730 may perform battery power regulation, DC-to-DC conversion, etc., and so has an input coupled to battery 1715, and an output providing a current supply to other functional modules. As further illustrated in FIG. 17, in the exemplary embodiment, RFIC 1725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1740 may provide memory functionality for sub-system 1760, high level control, data processing and the like for sub-system 1760. In alternative implementations, each of the SOC modules may be integrated onto separate ICs coupled to a package substrate, interposer, or board.

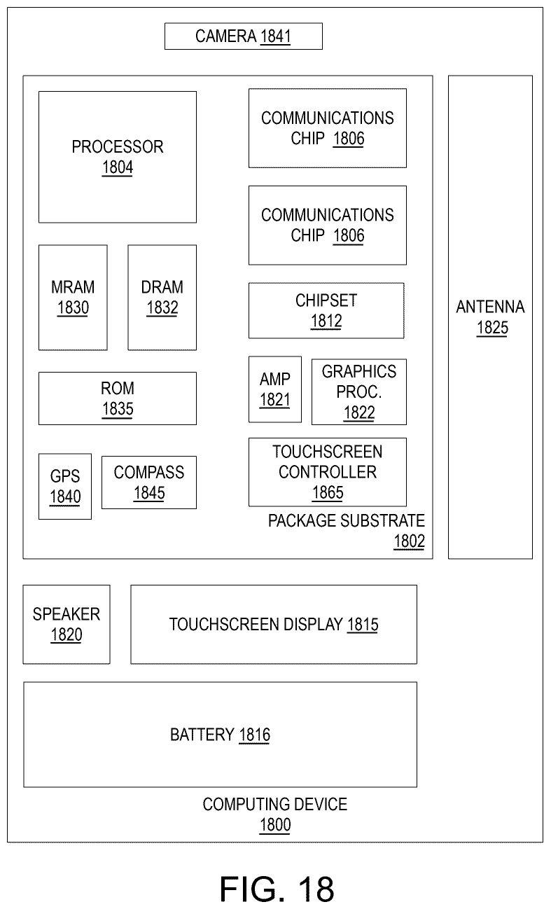

FIG. 18 is a functional block diagram of an electronic computing device 1800, in accordance with some embodiments. For example, device 1800 may, via any suitable component therein, employ an assembly including a liquid metal interconnect encapsulated within a cavity covered by a bilayer containment structure having a porous material layer and a self-healing material layer in accordance with any embodiments described elsewhere herein. For example, any component may be electrically coupled to a motherboard or package substrate 1802 via a liquid metal interconnect encapsulated within a cavity covered by a bilayer containment structure having a porous material layer and a self-healing material layer as discussed herein. Device 1800 further includes motherboard or package substrate 1802 hosting a number of components, such as, but not limited to, a processor 1804 (e.g., an applications processor). Processor 1804 may be physically and/or electrically coupled to motherboard or package substrate 1802. In general, the term “processor” or “microprocessor” may refer to any device or portion of a device that processes electronic data from registers and/or memory to transform that electronic data into other electronic data that may be further stored in registers and/or memory.

In various examples, one or more communication chips 1806 may also be physically and/or electrically coupled to motherboard or package substrate 1802. In further implementations, communication chips 1806 may be part of processor 1804. Depending on its applications, computing device 1800 may include other components that may or may not be physically and electrically coupled to motherboard or package substrate 1802. These other components include, but are not limited to, volatile memory (e.g., DRAM 1832), non-volatile memory (e.g., ROM 1835), flash memory (e.g., NAND or NOR), magnetic memory (MRAM 1830), a graphics processor 1822, a digital signal processor, a crypto processor, a chipset 1812, an antenna 1825, touchscreen display 1815, touchscreen controller 1865, battery 1816, audio codec, video codec, power amplifier 1821, global positioning system (GPS) device 1840, compass 1845, accelerometer, gyroscope, speaker 1820, camera 1841, and mass storage device (such as hard disk drive, solid-state drive (SSD), compact disk (CD), digital versatile disk (DVD), and so forth, or the like.

Communication chips 1806 may enable wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1806 may implement any of a number of wireless standards or protocols, including, but not limited to, those described elsewhere herein. As discussed, computing device 1800 may include a plurality of communication chips 1806. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertains to exemplary embodiments.

In one or more first embodiments, an apparatus comprises a substrate comprising an interconnect structure, a confinement layer over the substrate, the confinement layer defining a sidewall of a cavity over the interconnect structure, a metal within the cavity and over the interconnect structure, wherein the metal has a melting point of not more than 86° F., and a multilayer structure on the confinement layer and over the cavity, the multilayer structure comprising a first layer and a second layer, the first layer comprising a polymer and having an average pore size of not less than 1 nm and not more than 100 microns, and the second layer comprising particles comprising oxygen and a second metal or a metalloid.

In one or more second embodiments, further to the first embodiments, the average pore size is not less than 5 nm and not more than 50 microns.

In one or more third embodiments, further to the first or second embodiments, average pore size is not more than 25 microns.

In one or more fourth embodiments, further to the first through third embodiments, the first layer comprises one of polyurethane, polyimide, polypropylene, polystyrene, polyvinyl chloride, or polyethylene and silicone.

In one or more fifth embodiments, further to the first through fourth embodiments, the second metal comprises one of titanium, cerium, silicon, iron, zirconium, graphene, aluminum, or magnesium.

In one or more sixth embodiments, further to the first through fifth embodiments, the first layer has a thickness of not less than 10 microns and not more than 50 microns.

In one or more seventh embodiments, further to the first through sixth embodiments, the first layer has a first region over the cavity and a second region outside of the cavity, and wherein the second layer is on the first region and absent from the second region.

In one or more eighth embodiments, further to the first through seventh embodiments, the apparatus further comprises an adhesive between the first layer and the confinement layer.

In one or more ninth embodiments, further to the first through eighth embodiments, the apparatus further comprises one or more dies attached to a package substrate, and socket interconnects coupling the package substrate to the substrate, the socket interconnects comprising a pin extending through the multilayer structure.

In one or more tenth embodiments, an apparatus comprises a confinement layer over an electronic substrate, the confinement layer defining a sidewall of a cavity, a liquid metal within the cavity, and a containment structure on the confinement layer and over the cavity, the containment structure comprising a porous polymeric material layer and a self-healing material layer on the porous polymeric material layer, wherein the porous polymeric material layer comprises an average pore size of not less than 1 nm and not more than 100 microns.

In one or more eleventh embodiments, further to the tenth embodiments, the average pore size is not less than 5 nm and not more than 50 microns.

In one or more twelfth embodiments, further to the tenth or eleventh embodiments, the self-healing material layer comprises one of a metal oxide, a metalloid oxide, a gel adhesive, a microcapsule healing polymer, a cross-linked polymer, a thiol-based polymer, a vitrimer, a copolymer, or an epoxy resin.

In one or more thirteenth embodiments, further to the tenth through twelfth embodiments, the self-healing material layer comprises oxygen and titanium oxide particles.

In one or more fourteenth embodiments, further to the tenth through thirteenth embodiments, the porous polymeric material layer comprises one of polyurethane, polyimide, polypropylene, polystyrene, polyvinyl chloride, or polyethylene and silicone.

In one or more fifteenth embodiments, further to the tenth through fourteenth embodiments, the porous polymeric material layer has a thickness of not less than 10 microns and not more than 50 microns, wherein the porous polymeric material layer has a first region over the cavity and a second region outside of the cavity, and wherein the self-healing material layer is on the first region and absent from the second region.

In one or more sixteenth embodiments, further to the tenth through fifteenth embodiments, the apparatus further comprises one or more dies attached to a package substrate, and socket interconnects coupling the package substrate to the electronic substrate, the socket interconnects comprising a pin extending through the containment structure.

In one or more seventeenth embodiments, a method comprises receiving a confinement layer over an electronic substrate, the confinement layer defining a sidewall of a cavity, depositing a liquid metal in the cavity, forming a porous polymeric material layer on the confinement layer and over the cavity, wherein the porous polymeric material layer comprises an average pore size of not less than 1 nm and not more than 100 microns, and depositing a self-healing material layer on the porous polymeric material layer.

In one or more eighteenth embodiments, further to the seventeenth embodiments, forming the porous polymeric material layer on the confinement layer and over the cavity comprises receiving the porous polymeric material layer as a preform and adhering the preform to the confinement layer.

In one or more nineteenth embodiments, further to the seventeenth or eighteenth embodiments, depositing the self-healing material layer comprises one of spray coating the self-healing material layer on the porous polymeric material layer or brushing the self-healing material layer on the porous polymeric material layer.

In one or more twentieth embodiments, further to the seventeenth through nineteenth embodiments, the method further comprises contacting a pin of a socket interconnect to the liquid metal.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a substrate comprising an interconnect structure;
a confinement layer over the substrate, the confinement layer defining a sidewall of a cavity over the interconnect structure;
a metal within the cavity and over the interconnect structure, wherein the metal has a melting point of not more than 86° F.; and
a multilayer structure on the confinement layer and over the cavity, the multilayer structure comprising a first layer and a second layer, the first layer comprising a polymer and having an average pore size of not less than 1 nm and not more than 100 microns, and the second layer comprising particles comprising oxygen and a second metal or a metalloid.

2. The apparatus of claim 1, wherein the average pore size is not less than 5 nm and not more than 50 microns.

3. The apparatus of claim 2, wherein the average pore size is not more than 25 microns.

4. The apparatus of claim 1, wherein the first layer comprises one of polyurethane, polyimide, polypropylene, polystyrene, polyvinyl chloride, or polyethylene and silicone.

5. The apparatus of claim 1, wherein the second metal comprises one of titanium, cerium, silicon, iron, zirconium, graphene, aluminum, or magnesium.

6. The apparatus of claim 1, wherein the first layer has a thickness of not less than 10 microns and not more than 50 microns.

7. The apparatus of claim 6, wherein the first layer has a first region over the cavity and a second region outside of the cavity, and wherein the second layer is on the first region and absent from the second region.

8. The apparatus of claim 1, further comprising:
an adhesive between the first layer and the confinement layer.

9. The apparatus of claim 1, further comprising:
one or more dies attached to a package substrate; and
socket interconnects coupling the package substrate to the substrate, the socket interconnects comprising a pin extending through the multilayer structure.

10. An apparatus, comprising:
a confinement layer over an electronic substrate, the confinement layer defining a sidewall of a cavity;
a liquid metal within the cavity; and
a containment structure on the confinement layer and over the cavity, the containment structure comprising a porous polymeric material layer and a self-healing material layer on the porous polymeric material layer, wherein the porous polymeric material layer comprises an average pore size of not less than 1 nm and not more than 100 microns.

11. The apparatus of claim 10, wherein the average pore size is not less than 5 nm and not more than 50 microns.

12. The apparatus of claim 10, wherein the self-healing material layer comprises one of a metal oxide, a metalloid oxide, a gel adhesive, a microcapsule healing polymer, a cross-linked polymer, a thiol-based polymer, a vitrimer, a copolymer, or an epoxy resin.

13. The apparatus of claim 10, wherein the self-healing material layer comprises oxygen and titanium oxide particles.

14. The apparatus of claim 10, wherein the porous polymeric material layer comprises one of polyurethane, polyimide, polypropylene, polystyrene, polyvinyl chloride, or polyethylene and silicone.

15. The apparatus of claim 10, wherein the porous polymeric material layer has a thickness of not less than 10 microns and not more than 50 microns, wherein the porous polymeric material layer has a first region over the cavity and a second region outside of the cavity, and wherein the self-healing material layer is on the first region and absent from the second region.

16. The apparatus of claim 10, further comprising:
one or more dies attached to a package substrate; and
socket interconnects coupling the package substrate to the electronic substrate, the socket interconnects comprising a pin extending through the containment structure.

17. A method, comprising:
receiving a confinement layer over an electronic substrate, the confinement layer defining a sidewall of a cavity;
depositing a liquid metal in the cavity;
forming a porous polymeric material layer on the confinement layer and over the cavity, wherein the porous polymeric material layer comprises an average pore size of not less than 1 nm and not more than 100 microns; and
depositing a self-healing material layer on the porous polymeric material layer.

18. The method of claim 17, wherein forming the porous polymeric material layer on the confinement layer and over the cavity comprises receiving the porous polymeric material layer as a preform and adhering the preform to the confinement layer.

19. The method of claim 17, wherein depositing the self-healing material layer comprises one of spray coating the self-healing material layer on the porous polymeric material layer or brushing the self-healing material layer on the porous polymeric material layer.

20. The method of claim 17, further comprising:
contacting a pin of a socket interconnect to the liquid metal.
